(19) United States
(12) Patent Application Publication
(10) Pub. No.: US 2008/0106344 A1
(43) Pub. Date: May 8, 2008

(54) CIRCUIT ARRANGEMENT FOR A GPS SYSTEM

(76) Inventors: Tobias Frankenhauser, Emerkingen (DE); Richard Geissler, Weissenhorn (DE)

Correspondence Address: Muncy, Geissler, Olds & Lowe, PLLC, P.O. BOX 1364, FAIRFAX, VA, 22038-1364, US

(21) Appl. No.: 11/850,643

(22) Filed: Sep. 5, 2007

Related U.S. Application Data
(60) Provisional application No. 60/842,047, filed on Sep. 5, 2006.

(51) Int. Cl. H03B 25/00

(52) U.S. Cl. 331/48; 331/49

(57) ABSTRACT

A circuit arrangement, a system with at least one such circuit arrangement and a method for operating such a circuit arrangement is also provided. The circuit arrangement has at least two clock-controlled circuit sections and at least two oscillators that are designed to generate different clock frequencies. Switching means are provided that are designed to supply the at least two circuit sections with the same clock frequency in a first operating mode and to supply different circuit sections with different clock frequencies in a second operating mode. The circuit arrangement is preferably used in GPS-assisted navigation systems.

This nonprovisional application claims priority to U.S. Provisional Application No. 60/842,047, which was filed on Sep. 5, 2006, and is herein incorporated by reference.

### BACKGROUND OF THE INVENTION

1. Field of the Invention

The present invention relates to a circuit arrangement with at least two clock-controlled circuit elements and with at least two oscillators that are designed to generate different clock frequencies, a system with at least one such circuit arrangement, and a method for operating such a circuit arrangement.

2. Description of the Background Art

A circuit arrangement that is known from the market is set up for processing high-frequency electromagnetic satellite signals emitted by satellites in Earth orbit. The circuit arrangement is used in a receiver for a global positioning system (GPS receiver), for example. The task of the circuit arrangement is primarily to process the coded signals from the satellite in such a manner that position and/or time and/or velocity signals can be made available for further processing, for example by a navigation system. Since the satellite signals are typically very weak signals, amplification with a low-noise amplifier (LNA) and signal processing are provided before the coded signals are fed into the circuit arrangement. The amplified satellite signal is used as the input signal for a radio-frequency semiconductor component, or RF chip, that is provided for the processing of the input signal. The processed satellite signal is then provided to the circuit arrangement for further processing.

In normal operation, a variety of computational operations take place in the circuit arrangement; these operations are performed by the first circuit section, which is typically implemented as a processor. In order to ensure rapid provision of position and/or time and/or velocity signals, the first circuit section operates at a high clock frequency. This clock frequency is provided by a first oscillator and is typically in the megahertz range. The second circuit section is clock-controlled like the first circuit section; the clock frequency for the second circuit section is provided by a second oscillator. The second oscillator generates a clock frequency that is lower than the first clock frequency by at least a factor of ten.

The second circuit section is typically designed as a clock signal transmitter for providing a time signal that can be made available to the first circuit section. The high clock frequency of the first oscillator results in a high power consumption that is undesirable when the circuit arrangement is used in mobile, and in particular portable, GPS receivers. Instead, the goal is a low power consumption, so that the power or battery capacity that must be provided can be kept small. Thus, circuit arrangements for processing satellite signals are known that permit a reduction in the clock frequency with the aid of frequency dividers when the processor only needs to perform operations that are less computationally intensive. The power consumption is reduced due to the reduction in the clock frequency; however, the frequency dividers require additional power, so that only a slight power savings can be achieved.

### SUMMARY OF THE INVENTION

It is therefore an object of the present invention to provide a circuit arrangement, a system with such a circuit arrangement, and a method for operating such a circuit arrangement, which exhibit a reduced power consumption.

The circuit arrangement according to an embodiment of the present invention has switches that are designed to supply at least two circuit sections with the same clock frequency in a first operating mode and to supply different circuit sections with different clock frequencies in a second operating mode. In the second operating mode, the at least two circuit sections are operated with different clock frequencies. These different clock frequencies are the clock frequencies of the at least two oscillators, so that the first circuit section is operated at the frequency of the first oscillator and the second circuit section is operated at the frequency of the second oscillator. In this operating state, the first circuit section can perform rapid computational operations and can, for example, calculate a position and/or time and/or velocity signal from satellite signals, for which a number of computational operations is required. In the second operating mode, the at least two, and preferably all, circuit sections are operated at the same clock frequency, which typically is lower than the clock frequency of the first oscillator. The computational operations for determining the position and/or time and/or velocity signals from the satellite signals cannot be performed at this lower clock frequency, since the computational speed is too low for this purpose. Nonetheless, relatively simple operations can be performed by the first circuit section, for example in order to operate a display device such as an LCD display and to display, e.g., a time thereon. The switching means make it possible to provide the clock frequency of one of the at least two oscillators to the at least two circuit sections, or alternatively to provide the first clock frequency to the first circuit section and the second clock frequency to the second circuit section. Switching between operating modes can be performed by the user or automatically. Automated switching from the second operating mode to the first, energy-saving operating mode can be provided, for example, when no change in position has taken place, and/or no velocity has been detected, over a relatively long, predefinable period of time.

In one embodiment of the invention, provision is made for the first oscillator to have a clock frequency that is more than 100 times, preferably more than 500 times, especially preferably more than 700 times, the frequency of the second oscillator. In this way, a switch of the clock frequency for the first circuit section from the first clock frequency of the first oscillator to the second clock frequency of the second oscillator brings about a significant slowing of the computing power for the first circuit. This slowing also achieves a considerable reduction in the power consumption of the first circuit section, without requiring additional power as a result of the reduced clock frequency as would be the case with the use of frequency dividers. In a preferred embodiment of the invention, provision is made for the first oscillator to be set up for a clock frequency greater than 15 MHz, in particular 23.104 MHz, and for the second oscillator to be set up for a clock frequency that is less than 50 kHz, in particular 32.768 kHz.

In another embodiment of the invention, provision is made for the first circuit section to be designed as a processor for determining position and/or time and/or velocity signals from the satellite signals. In this way, the circuit arrangement can be used in GPS devices that are permanently installed or are designed as mobile devices.

In another embodiment of the invention, provision is made for the second circuit section to be designed as a time measurement device, in particular as a real-time clock, for providing a time signal that is used in determining position and/or time and/or velocity signals from the satellite signals. Precise knowledge of the system time is necessary for determining a position and/or time and/or velocity signal from satellite signals. This system time is made available to the first circuit section by the second circuit section, which is designed as an internal time measurement device, and is thus immediately available when needed. Calibration of the system time takes place with the aid of the coded satellite signals; the calibration process required for this purpose is performed periodically.

In another embodiment of the invention, provision is made that the first oscillator has associated with it at least one frequency divider designed for reducing the clock frequency of the first oscillator. The at least one frequency divider makes it possible to provide an additional frequency that resides between the frequencies of the first and second oscillators. For example, this additional clock frequency can be made available through a signal line to an external circuit, which can thus be operated synchronously with the first circuit device.

In another embodiment of the invention, provision is made that the switching means can be switched into an operating mode in which a clock frequency reduced by the at least one frequency divider is provided to at least one circuit section. Thus, as needed, the switching means can pass on the clock frequency of the first oscillator to the first circuit section, either directly or through the frequency divider, or else can make the clock frequency of the second oscillator available to the first circuit section. In this way, for example, power-saving execution of less complex calculations can be provided for the first circuit section. Thus, at least three different frequencies are made available to the first circuit section as a function of the computing power required, making it possible to realize advantageous, energy-saving adaptation of the clock frequency for the first circuit section to differing needs.

In another embodiment of the invention, provision is made that the switching means are set up to temporarily generate a switchover frequency which is synchronous with the clock frequency of the circuit section to be switched and which has the target frequency for the circuit section to be switched. In switching the first circuit section between the different clock frequencies, it is necessary to ensure that the processor remains glitch-free during the transition in each case, which is to say free from wrong logic results. A glitch in the first circuit section could be caused when an immediate switchover is performed from the clock frequency of the first oscillator to the clock frequency of the second oscillator, which frequencies are typically not synchronized. For example, a switchover at a time when the applicable first clock frequency has a falling edge and the second clock frequency has a rising edge could result in an excessively high effective frequency for the circuit section, which could enter an unwanted state as a result. In order to avoid this, the switching means provide, at least temporarily, a synchronized switchover frequency for the circuit section for switching the clock frequencies. The switchover frequency is obtained from the relevant clock frequency present at the circuit section, by which means it is automatically synchronized with this clock frequency. The switchover frequency already has the clock frequency that is to be present at the circuit section after the switchover. In this way, it is possible to prevent the circuit section whose clock frequency is to be switched over from entering an unwanted state at the transition.

The object of the invention in accordance with a second aspect is attained by a system having an antenna device for receiving satellite signals; an amplifier circuit for amplifying the satellite signals; and a processing circuit for the satellite signals. With such a system, the reception of satellite signals, the amplification of these signals, and their processing are possible. The system provides as its output signal a position and/or time and/or velocity signal that can be processed by a following circuit.

The object of the invention in accordance with a third aspect is attained by a method, wherein in a normal mode the clock frequency of the first oscillator is present at the first circuit section and the clock frequency of the second oscillator is present at the second circuit section, and wherein in a sleep mode the clock frequency of the second oscillator is present at the first and second circuit sections. With this method, the high clock frequency of the first oscillator can be used for rapid execution of a variety of calculations in the first circuit section in the normal mode. In the second operating mode, also known as sleep mode, no calculation of position and/or time and/or velocity signals from satellite signals takes place. However, basic functions such as display of clock time on a display device can be ensured, wherein an especially low power consumption can be ensured because of the low clock frequency. Preferably, the first circuit section is operated at a clock frequency in the normal mode that is more than 100 times, preferably more than 500 times, especially preferably more than 700 times, the second clock frequency. In this way, a considerable power-saving effect can be achieved through the use of the second clock frequency.

In another embodiment of the invention, provision is made that in an economy mode the first circuit section is operated at a reduced clock frequency which is obtained by dividing the first clock frequency by a divisor that is preferably an integer. In the economy mode, the first circuit section is operated at a clock frequency that is smaller than in the normal mode by, e.g., a factor of 2, 4, 8, or 16, while still permitting at least the execution of relatively simple computational operations. In this way, a power savings is achieved relative to the normal mode.

In another embodiment of the invention, provision is made that a switchover frequency that is synchronous with the first clock frequency and has the same frequency as the second clock frequency is temporarily applied to the first circuit section to switch the first circuit section from the first clock frequency to the second clock frequency. This prevents the brief application of an excessively high clock frequency during the switchover from the first clock frequency to the second clock frequency, which could occur as a result of an unfavorable sequence of rising or falling edges of the two clock frequencies to be switched. As a result, wrong logic results could occur in the circuit section whose clock frequency is to be switched. This applies to a switch from a high clock frequency to a low clock frequency as well as to a switch from a low clock frequency to a high clock frequency, hence during a switchover of the first circuit section from the second clock frequency to the first clock frequency.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 is a schematic representation of a GPS receiver unit that is provided for use in a satellite navigation system,

FIG. 2 is a schematic representation of a receiver multichip module of the GPS receiver unit from FIG. 1,

FIG. 3 is a schematic diagram of switching means for switching a circuit section between a first clock frequency and at least one second clock frequency,

FIG. 4 is a diagram of signal behavior for the switching means from FIG. 3 during a switch from a first, higher clock frequency to a second, lower clock frequency, and

FIG. 5 is a diagram of signal behavior for the switching means from FIG. 3 during a switch from a second, lower clock frequency to a first, higher clock frequency.

### DETAILED DESCRIPTION

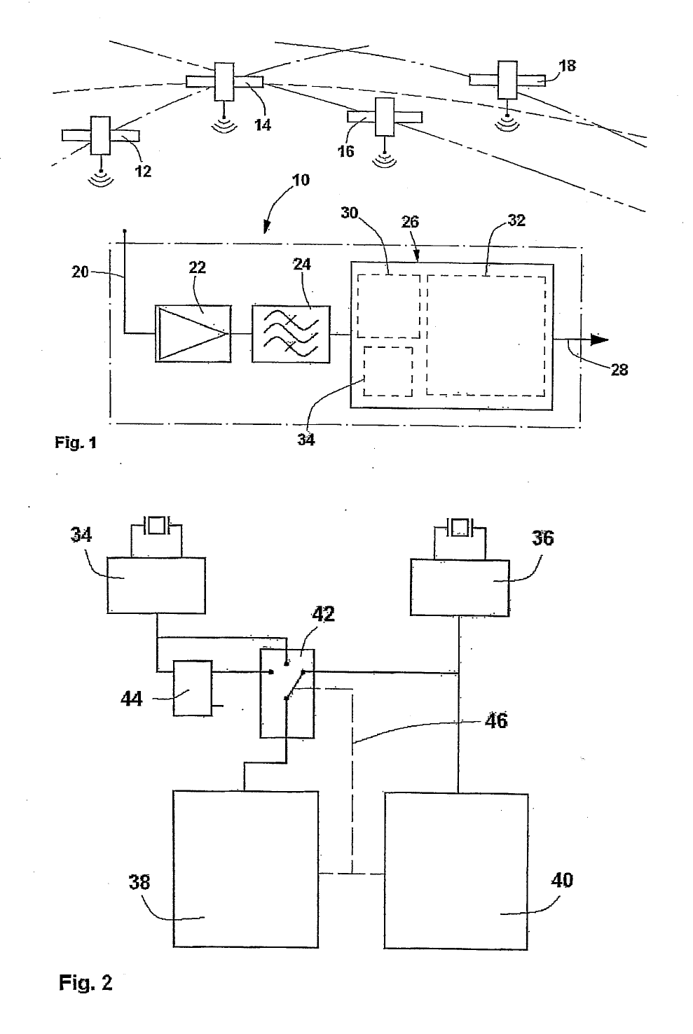

FIG. 1 schematically shows a GPS receiver 10 that is intended for receiving signals from multiple satellites 12 through 18 that are located in different Earth orbits. The satellites 12 through 18 transmit coded signals that can be distinguished from one another and that are typically transmitted at a frequency of 1.575 GHz, and that can be received by an antenna 20 of the GPS receiver 10. The antenna 20 is connected to a low-noise amplifier 22 (LNA) that amplifies the weak signals from the satellites 12 through 18 and that is set up so that a signal-to-noise ratio of the satellite signals is not degraded at all or is degraded only slightly. The amplified satellite signals are filtered with the aid of a surface acoustic wave (SAW) filter 24 that acts as a bandpass filter, and are then supplied as an input signal for a receiver multichip module 26. The receiver multichip module 26 has a radio-frequency semiconductor component or RF chip 30 that is provided for conditioning the input signal. Also provided on the receiver multichip module 26 is a digital semiconductor component or digital chip 32 that performs further processing of the conditioned input signal.

Following processing in the digital chip 32, an output signal 28 is provided by the receiver multichip module 26; said output signal can be provided for further processing by electronic circuits that are not shown. In particular, the output signal 28 can contain position and/or time and/or velocity signals extracted with the aid of the GPS receiver from the different signals from the satellites 12 through 18.

As shown schematically in FIG. 2, in addition to the RF chip 30 and the digital chip 32, two oscillators 34 and 36 embodied as discrete components are also located on the receiver multichip module 26, which have the purpose of providing different clock frequencies.

The digital chip 32 is subdivided into multiple circuit sections, which are designed to provide different functions. A first circuit section of the digital chip 32 is designed as a clock-controlled processor 38, and allows the performance of computational operations, where a computing speed of the processor 38 depends upon the applied clock frequency. A second circuit section of the digital chip 32 is designed as a clock-controlled time measurement device 40 with a real-time clock (RTC). Another circuit section of the digital chip 32 is designed as a switching 42, and is provided to variably supply the clock frequencies of the oscillators 34, 36 to the first circuit section 38 and to supply the clock frequency of the second oscillator to the second circuit section 40. By way of example, the switch 42 has associated with it a frequency divider 44 designed as a flip-flop, which is intended for reducing the high clock frequency supplied by the first oscillator 34. It is also possible for multiple frequency dividers, which in particular are arranged in a cascade, to be associated with the switching means, making it possible to supply different frequencies. The switch 42 can have three different switch settings and thus makes it possible to supply three different clock frequencies to the processor 38. Switching between the different clock frequencies is accomplished by means of switching signals that are supplied by the processor 38 or by the time measurement device 40 and are conducted to the switching means 42 over a signal line 46.

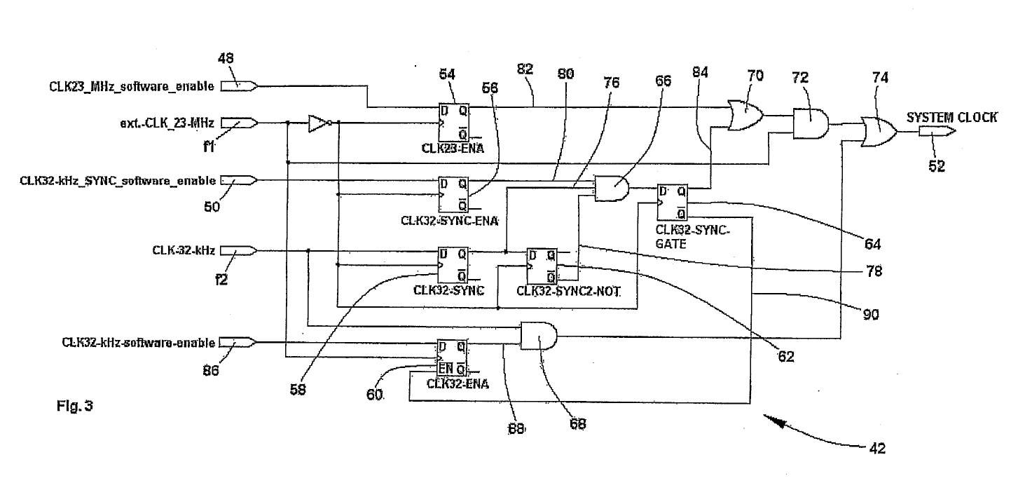

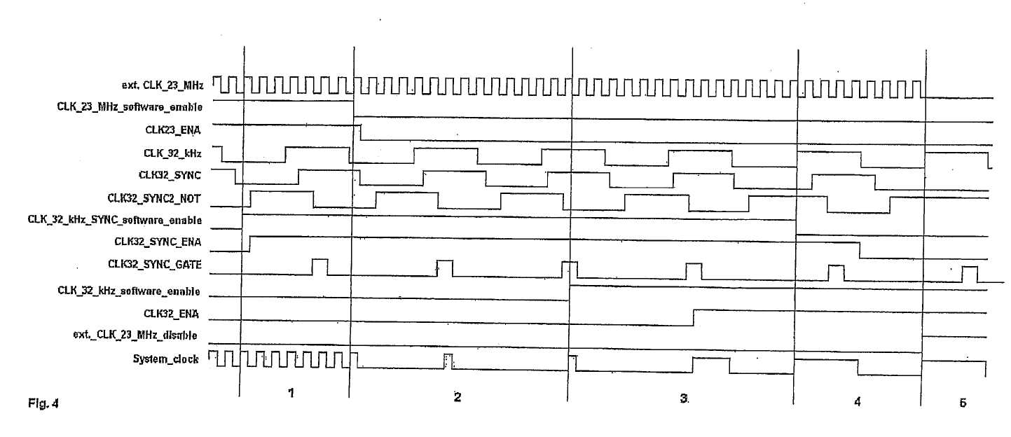

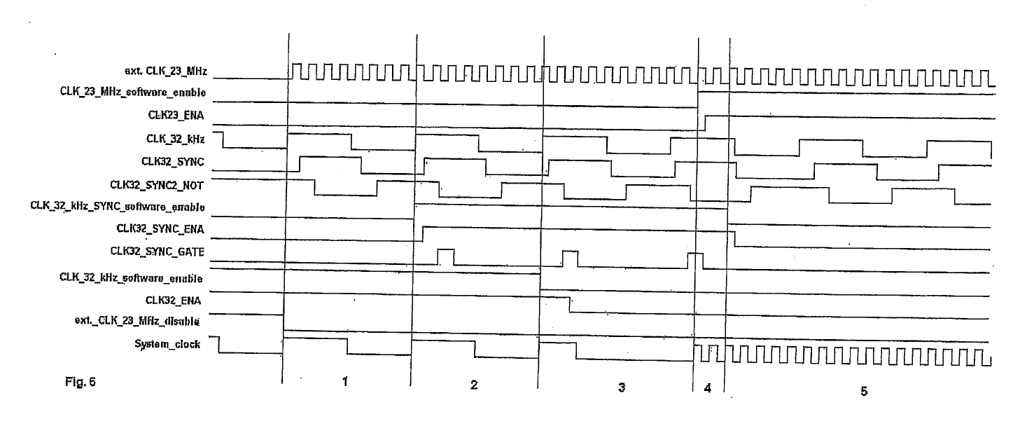

As shown in detail in FIG. 3, the switch 42 has a logic circuit with multiple D flip-flops (delay flip-flops), multiple AND gates, and multiple OR gates. The logic circuit is constructed such that glitch-free switching between the clock frequencies can be ensured. To this end, different input signals, which are supplied by the oscillators 34, 36 and also are supplied over the signal line 46 by the processor 38 or by the time measurement device 40, are applied to inputs of the logic circuit. An explanation of how the switchover between different clock frequencies can be undertaken with the aid of the switch 42 is given below. The input signals supplied to the logic circuit, the internal signals generated within the logic circuit, and the resulting clock signal 52 (system clock) output by the logic circuit are shown in the diagram of signal behavior in FIG. 4 for the switchover from a high to a low clock frequency, and are shown in the signal behavior diagram in FIG. 5 for the switchover from a low to a high clock frequency.

The high clock frequency f1 of the first oscillator 34 labeled “ext. CLK23MHz,” and the lower clock frequency f2 of the second oscillator 36 labeled “CLK32kHz” are supplied as input signals for the logic circuit. Also present at the inputs of the logic circuit are the control signal 48 (CLK23MHz_software_enable), the control signal 50 (CLK32kHz_SYNC_software_enable), and the control signal 86 (CLK32kHz_software_enable), which are supplied by the processor 38 or by the time measurement device 40.

As is evident from the signal behavior diagram in FIG. 4, the resultant clock signal 52 in the first time segment of the signal behavior diagram corresponds to the high clock frequency f1. The low clock frequency f2 that is also applied to the logic circuit is supplied in the D flip-flops 58 and 62 using the inverted high clock frequency f1, which serves to switch the D flip-flops, as the synchronous clock signal 76 (CLK32_SYNC) and as the inverted synchronous clock signal 78 (CLK32_SYNC_NOT). Due to the signal propagation delay in the D flip-flop 58, the inverted synchronous clock signal 78 generated by the following D flip-flop 62 is time-delayed with respect to the synchronous clock signal 76.

At the start of the time segment 1, the control signal 50 (CLK32MHz_SYNC_software_enable), which is present at the D flip-flop 56, is switched to a high level. After the appearance of the next rising edge of the high clock frequency f1 that is applied to the clock input of the D flip-flop 56, the internal signal 80 (CLK32_SYNC_ENA) can be provided by the D flip-flop 56 to the dual AND gate 68. The synchronous clock signal 76 (CLK32_SYNC) and the inverted synchronous clock signal 78 (CLK32_SYNC_NOT) are applied to the other inputs of the dual AND gate 68. The dual AND gate 68 supplies an input signal for the D flip-flop 64, which is likewise driven by the inverted clock signal with the high frequency f1. Consequently, the D flip-flop 64 supplies an internal switching signal 84 (CLK_SYNC_GATE) to the OR gate 70 when the appropriate levels of the signals 50 (CLK32MHz_SYNC_software_enable), 76 (CLK32_SYNC), 78 (CLK32_SYNC_NOT), and the clock signal at the high frequency f1 are present. During the time segment 1, the high clock frequency f1 continues to be output as the resultant clock signal 52.

At the start of the time segment 2, the control signal 48 (CLK23MHz_software_enable) is switched off, causing the internal switching signal 82 (CLK23_ENA) that is output by the D flip-flop 54 and is present at the OR gate 70 to drop to a low level as well. In this way, the OR gate 70 can only be enabled and supply an input signal for the subsequent AND gate 72 in the presence of a high level of the internal switching signal 84 (CLK32_SYNC_GATE). Thus, the clock signal with the high frequency f1 that is present at the AND gate 72 can only be output as the resulting clock signal 52 in the presence of a high level of the switching signal 84 (CLK32_SYNC_GATE). In the signal behavior diagram in FIG. 4, this can be seen in the fact that during the time segment 2 a high level of the resulting clock signal 52 is only present when a high level of the internal switching signal 84 (CLK32_SYNC_GATE) is present.

At the start of the time segment 3, the control signal 86 (CLK32kHz_software_enable) is set to a high level. As a result, the D flip-flop 60 makes the internal switching signal 88 (CLK32_ENA) available starting from the point in time at which the clock signal with the high frequency f1 has the next rising edge at the same time that the internal switching signal 84 (CLK32_SYNC_GATE) is at a high level. Starting at this point in time, the AND gate 66 makes the clock signal with the low frequency f2 available to the OR gate 74; this clock signal is synchronized with the clock signal having the high frequency f1 and serves as a switching signal.

In this way, starting with time segment 4, the clock signal with the low frequency f2 is output as the resulting clock signal 52. Starting with the time segment 4, the control signal 50 (CLK32kHz_SYNC_software_enable) can be set to a low level, and starting with time segment 5, the clock signal with the high frequency f1 is switched off, completing the glitch-free clock frequency switching.

A similar procedure is followed for the switchover from the clock signal with the low frequency f2 to the clock frequency with the high frequency f1, as is shown in FIG. 5. At the start of the time segment 1, the clock signal with the high frequency f1 is switched on; subsequently, at the start of the time segment 2, the control signal 50 (CLK32kHz_SYNC_software_enable) is set to a high level. At the start of the time segment 3, the control signal 86 (CLK32kHz_software_enable) is set to a low level. At the beginning of the time segment 4, the control signal 48 (CLK23MHz_software_enable) is set to a high level, and at the start of the time segment 5, the control signal 50 (CLK32kHz_SYNC_software_enable) can be set to a low level, completing the glitch-free clock frequency switching.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A circuit arrangement comprising:
at least two clock-controlled circuit elements;
at least two oscillators that are designed to generate different clock frequencies; and
a switch for supplying the at least two circuit sections with the same clock frequency in a first operating mode and to supply different circuit sections with different clock frequencies in a second operating mode.

2. The circuit arrangement according to claim 1, wherein the first oscillator has a clock frequency that is more than 100 times or more than 500 times or more than 700 times the clock frequency of the second oscillator.

3. The circuit arrangement according to claim 2, wherein the first oscillator is set up for a clock frequency greater than 15 MHz, and wherein the second oscillator is set up for a clock frequency that is less than 50 KHz.

4. The circuit arrangement according to claim 1, wherein the first circuit section is designed as a processor for determining position and/or time and/or velocity signals from satellite signals.

5. The circuit arrangement according to claim 1, wherein the second circuit section is designed as a time measurement device or a real-time clock, for providing a time signal, and is used in determining position and/or time and/or velocity signals from satellite signals.

6. The circuit arrangement according to claim 1, wherein the first oscillator has associated with it at least one frequency divider designed for reducing the clock frequency of the first oscillator.

7. The circuit arrangement according to claim 6, wherein the switch is switched into an operating mode in which a clock frequency reduced by the at least one frequency divider is provided to at least one circuit section.

8. The circuit arrangement according to claim 1, wherein the switch is set up to temporarily generate a switchover frequency that is synchronous with the clock frequency of the circuit section to be switched and that has the target frequency for the circuit section to be switched.

9. A system comprising:
a circuit arrangement;
an antenna device for receiving satellite signals;
an amplifier circuit for amplifying the satellite signals; and
a processing circuit for processing the satellite signals
wherein the circuit arrangement comprises:
at least two clock-controlled circuit elements;
at least two oscillators that are designed to generate different clock frequencies; and
a switch for supplying at least two circuit sections with the same clock frequency in a first operating mode and to supply different circuit sections with different clock frequencies in a second operating mode.

10. A Method for operating a circuit arrangement, the method comprising:
providing the circuit arrangement, the circuit arrangement including at least two clock-controlled circuit elements, at least two oscillators, and a switch;
generating different clock frequencies by the at least two oscillators; and
supplying, via the switch, at least two circuit sections with the same clock frequency in a first operating mode and to supply different circuit sections with different clock frequencies in a second operating mode,
wherein in a normal mode the clock frequency of the first oscillator is present at a first circuit section and the clock frequency of the second oscillator is present at a second circuit section, and
wherein in a sleep mode the clock frequency of the second oscillator is present at the first and second circuit sections.

11. The method according to claim 10, wherein the first circuit section is operated in the normal mode at a clock frequency that is more than 100 times or more than 500 times or more than 700 times, the second clock frequency.

12. The method according to claim 10, wherein the first circuit section is operated in an economy mode at a reduced clock frequency that is obtained by dividing the first clock frequency by a divisor that is preferably an integer.

13. The method according to claim 10, wherein a switchover frequency that is synchronous with the first clock frequency and has the same frequency as the second clock frequency is temporarily applied to the first circuit section to switch the first circuit section from the first clock frequency to the second clock frequency.

14. The method according to claim 10, wherein a switchover frequency that is synchronous with the second clock frequency and has the same frequency as the first clock frequency is temporarily applied to the first circuit section to switch the first circuit section from the second clock frequency to the first clock frequency.
